(19) United States
(12) Patent Application Publication
(10) Pub. No.: US 2024/0035199 A1
(43) Pub. Date: Feb. 1, 2024

(54) SINGLE-CRYSTALLINE STACK STRUCTURE OF TWO-DIMENSIONAL TRANSITION METAL CHALCOGENIDE AND METHOD OF FABRICATING THE SAME

(71) Applicant: RESEARCH & BUSINESS FOUNDATION SUNGKYUNKWAN UNIVERSITY, Gyeonggi-do (KR)

(72) Inventors: Ki Kang KIM, Suwon-si (KR); Seokjoon YUN, Hwaseong-si (KR); Soo Ho CHOI, Uiwang-si (KR)

(73) Assignee: RESEARCH & BUSINESS FOUNDATION SUNGKYUNKWAN UNIVERSITY, Gyeonggi-do (KR)

(21) Appl. No.: 17/974,994

(22) Filed: Oct. 27, 2022

(30) Foreign Application Priority Data
Jul. 27, 2022 (KR) 10-2022-0093176

(51) Int. Cl. C30B 29/68; C30B 29/46; C30B 25/18

(52) U.S. Cl. CPC C30B 29/68; C30B 29/46; C30B 25/186

(57) ABSTRACT

Disclosed are stack structures and their fabrication methods. The method comprises providing a growth chamber with a first two-dimensional material layer, forming a defect on a surface the first two-dimensional material layer, and forming a second two-dimensional material layer on the first two-dimensional material layer. The step of forming the second two-dimensional material layer includes supplying the growth chamber with a transition metal precursor and a chalcogen precursor, and reacting the first two-dimensional material layer and the transition metal precursor with each other.

### CROSS-REFERENCE TO RELATED APPLICATION

This U.S. nonprovisional application claims priority under 35 U.S.C § 119 to Korean Patent Application No. 10-2022-0093176 filed on Jul. 27, 2022 in the Korean Intellectual Property Office, the disclosure of which is hereby incorporated by reference in its entirety.

### BACKGROUND

Some embodiments of the present inventive concepts relate to a stack structure and a method of fabricating the same, and more particularly, to a stack structure including a two-dimensional material layer and a method of fabricating the same.

Two-dimensional transition metal dichalcogenides have been researched and developed in various fields such as solar cells, photo-detectors, and light-emitting diodes because of their own chemical and physical properties as conductor and semiconductor materials.

Typically, in atomically thin two-dimensional materials, a reduction in thickness of a matter induces an increase in ratio of mass to surface of the matter increases, which results in an increase in surface area of the matter per unit mass. In addition, as the energy state of an electron reaches closer to that of a molecule, there appear physical properties completely different from those of a bulk material. An increase in surface area and an activation of the atomically thin two-dimensional materials, like the melting point thereof, influences a variation in physical properties and also influences a variation in optical and electrical properties by quantum effects, with the result that the atomically thin two-dimensional materials may be applied to novel optoelectronic materials.

Because the atomically thin two-dimensional transition metal dichalcogenides are applicable to biological markers, nonlinear optical materials, light-emitting devices, photo-sensors, catalysts, chemical sensors, and so forth, diverse methods have been attempted to more efficiently synthesize the transition metal dichalcogenides in the form of thin films.

### SUMMARY

Some embodiments of the present inventive concepts provide a single-crystalline stack structure including two-dimensional material layers having the same crystal orientation and a method of fabricating the same.

According to some embodiments of the present inventive concepts, a method of fabricating a stack structure may comprise: providing a growth chamber with a first two-dimensional material layer; forming a defect on the first two-dimensional material layer; and forming a second two-dimensional material layer on the first two-dimensional material layer. The step of forming the second two-dimensional material layer may include: supplying the growth chamber with a transition metal precursor and a chalcogen precursor; and reacting the first two-dimensional material layer and the transition metal precursor with each other.

According to some embodiments of the present inventive concepts, a method of fabricating a stack structure may comprise: providing a growth chamber with a first two-dimensional material layer; forming a defect on the first two-dimensional material layer; and forming a second two-dimensional material layer on the first two-dimensional material layer. The step of forming the second two-dimensional material layer may include: supplying the growth chamber with a transition metal precursor and a chalcogen precursor; and radicalizing the transition metal precursor and the chalcogen precursor.

According to some embodiments of the present inventive concepts, a stack structure may comprise: a first two-dimensional material layer that includes first transition metal atoms and first chalcogen atoms; and a second two-dimensional material layer on the first two-dimensional material layer, the second two-dimensional material layer including second transition metal atoms and second chalcogen atoms. The first two-dimensional material layer and the second two-dimensional material layer may have the same crystal orientation.

### BRIEF DESCRIPTION OF THE DRAWINGS

FIG. 1 illustrates an apparatus for fabricating a stack structure according to some embodiments.

FIGS. 2A, 2B, 2C, 2D, 2E, and 2F illustrate a method of fabricating a stack structure according to some embodiments.

FIG. 3A illustrates the crystal orientation of a stack structure according to some embodiments.

FIG. 3B illustrates the crystal orientation of a stack structure according to some embodiments.

FIG. 3C illustrates the crystal orientation of a stack structure according to a comparative example.

FIGS. 4A and 4B illustrate optical microscopic images showing results by a method of fabricating a stack structure according to a comparative example.

FIGS. 5A and 5B illustrate optical microscopic images showing results by a method of fabricating a stack structure according to some embodiments.

FIG. 6 illustrates a graph showing the Raman spectrum of a stack structure according to some embodiments.

FIG. 7 illustrates the photoluminescence spectrum of a stack structure according to some embodiments.

FIGS. 8A, 8B, and 8C illustrate images showing the crystal orientation of a stack structure according to some embodiments.

FIGS. 9A, 9B, 9C, and 9D illustrate transmission electron microscope (TEM) images showing a stack structure according to some embodiments.

FIG. 10 illustrates an electron diffraction pattern showing a lattice mismatch of a stack structure according to some embodiments.

### DETAIL PARTED DESCRIPTION OF EMBODIMENTS

The following will now describe in detail a stack structure and a method of fabricating the same according to some embodiments of the present inventive concepts in conjunction with the accompanying drawings.

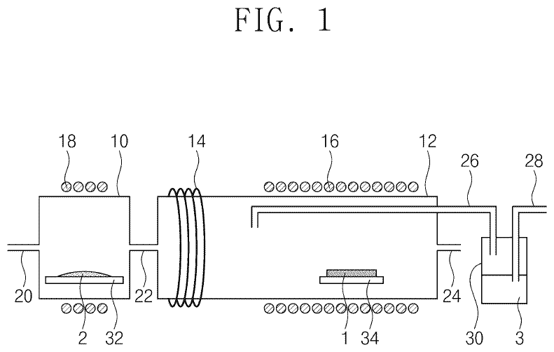

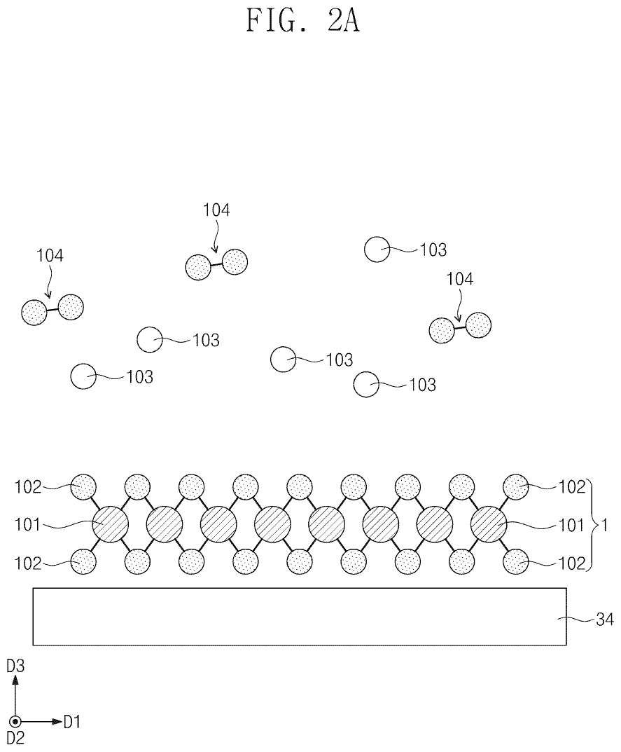

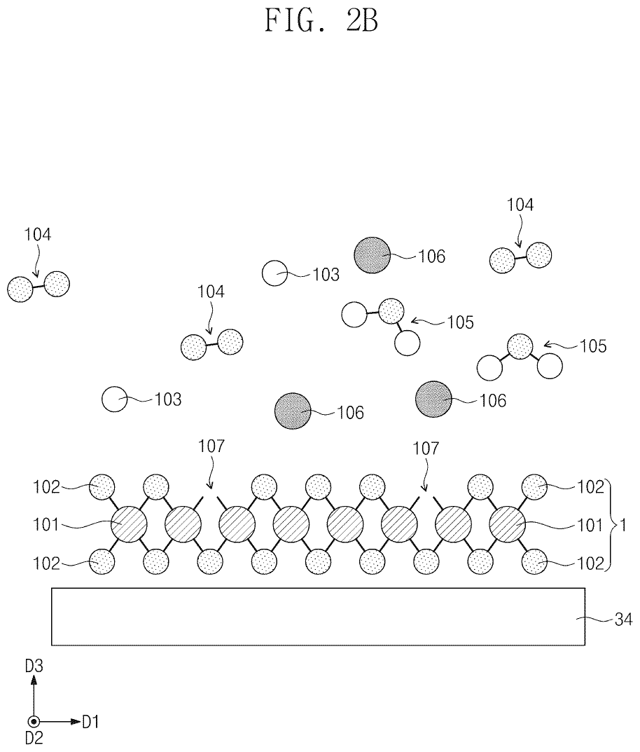

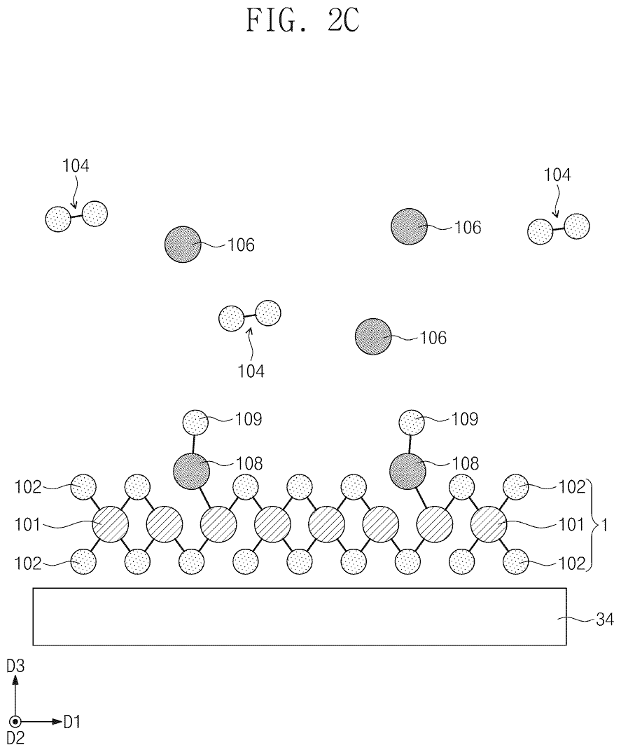

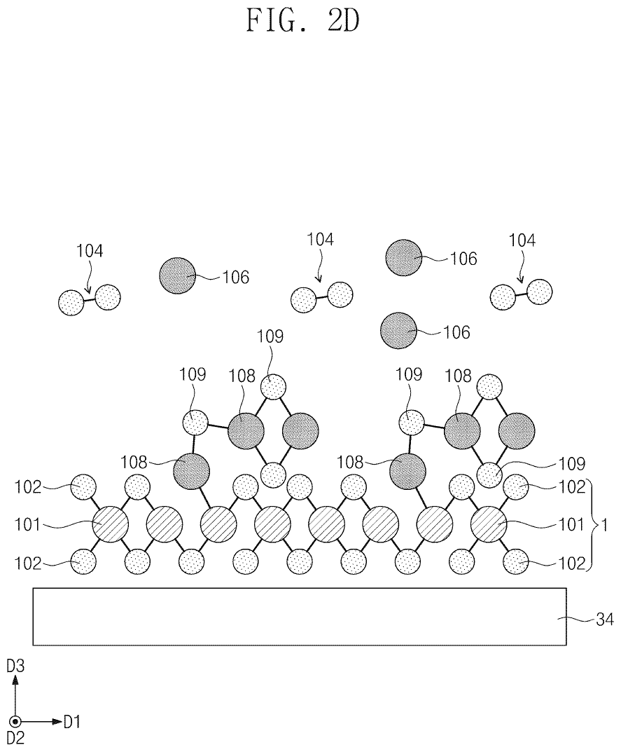

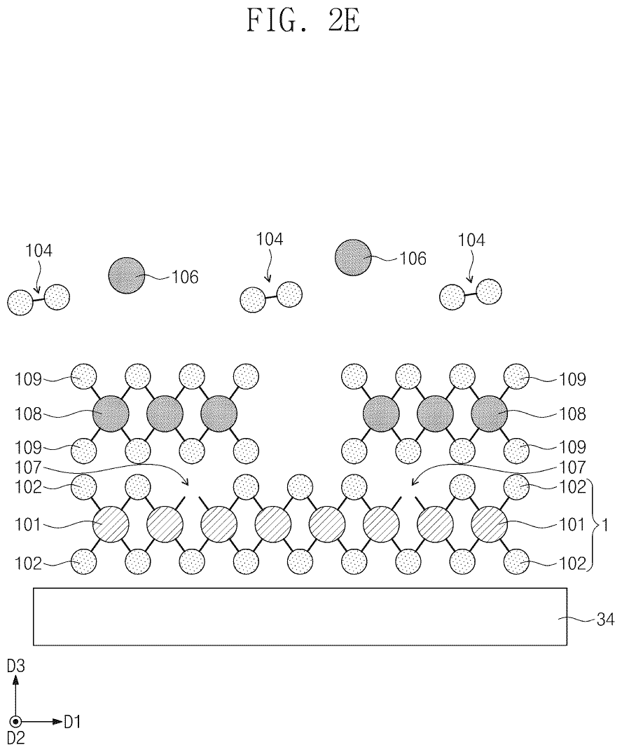

FIG. 1 illustrates an apparatus for fabricating a stack structure according to some embodiments. FIGS. 2A, 2B, 2C, 2D, 2E, and 2F illustrate a method of fabricating a stack structure according to some embodiments.

Referring to FIG. 1, a fabrication apparatus may include a vaporization chamber 10, a growth chamber 12, a plasma generation device 14, a first heater 16, a second heater 18, a first supply line 20, a connection line 22, an exhaustion line 24, a second supply line 26, a third supply line 28, a bubbler chamber 30, a first substrate 32, and a second substrate 34.

The vaporization chamber 10 may include an empty space therein. The vaporization chamber 10 may be, for example, a quartz tube. The first substrate 32 may be disposed in the vaporization chamber 10. The first supply line 20 may be connected to the vaporization chamber 10. The connection line 22 may be connected to the vaporization chamber 10.

The second heater 18 may heat the vaporization chamber 10. The second heater 18 may be, for example, a heating belt that surrounds the vaporization chamber 10.

The growth chamber 12 may include an empty space therein. The growth chamber 12 may be, for example, a quartz tube. The second substrate 34 may be disposed in the growth chamber 12. The connection line 22 may be connected to the growth chamber 12. The connection line 22 may connect the vaporization chamber 10 and the growth chamber 12 to each other. The exhaustion line 24 may be connected to the growth chamber 12.

In some embodiments, a rotary pump may be connected to the exhaustion line 24, and an operation of the rotary pump may allow the growth chamber 12 to exhaust a gas therefrom. The rotary pump may operate to cause the growth chamber 12 to have therein a pressure equal to or less than about 10 Torr.

The first heater 16 may heat the growth chamber 12. The first heater 16 may be, for example, a heating belt that surrounds the growth chamber 12.

The plasma generation device 14 may generate plasma in the growth chamber 12. The plasma generation device 14 may be, for example, an inductive coil that surrounds the growth chamber 12. The plasma generation device 14 may be as remote plasma generation device.

The bubbler chamber 30 may include an empty space therein. The second supply line 26 may connect the growth chamber 12 and the bubbler chamber 30 to each other. The third supply line 28 may be connected to the bubbler chamber 30.

Referring to FIGS. 1 and 2A, the growth chamber 12 may be provided with a first two-dimensional material layer 1. The first two-dimensional material layer 1 may be provided on the second substrate 34 in the growth chamber 12.

The first two-dimensional material layer 1 may include a two-dimensional material including first transition metal atoms 101 and first chalcogen atoms 102. The first transition metal atom 101 may be, for example, a molybdenum (Mo) atom or a tungsten (W) atom. The first chalcogen atom 102 may be, for example, a sulfur (S) atom, a selenium (Se) atom, or a tellurium (Te) atom.

The first two-dimensional material layer 1 may have a planar structure that extends along a plane defined by a first direction D1 and a second direction D2. The first direction D1 and the second direction D2 may intersect each other. For example, the first direction D1 and the second direction D2 may be horizontal directions that are orthogonal to each other. A third direction D3 may intersect the first direction D1 and the second direction D2. For example, the third direction D3 may be a vertical direction perpendicular to the first direction D1 and the second direction D2.

The growth chamber 12 may be supplied with a hydrogen radical 103. The hydrogen radical 103 may be a hydrogen atom including an unpaired electron. The supply of the hydrogen radical 103 into the growth chamber 12 may include supplying a hydrogen gas through the first supply line 20 to the vaporization chamber 10, supplying a hydrogen gas from the vaporization chamber 10 through the connection line 22 to the growth chamber 12, and using the plasma generation device 14 to radicalize the hydrogen gas supplied into the growth chamber 12. The hydrogen gas may be radicalized by the plasma generation device 14, and thus the hydrogen radical 103 may be formed.

The growth chamber 12 may be supplied with a radicalized chalcogen precursor 104. The radicalized chalcogen precursor 104 may include an unpaired electron and have relatively large reactivity. The supply of the radicalized chalcogen precursor 104 into the growth chamber 12 may include providing a chalcogen precursor 2 onto the first substrate 32 in the vaporization chamber 10, using the second heater 18 to allow the chalcogen precursor 2 to be vaporized to form a chalcogen precursor gas, supplying the chalcogen precursor gas from the vaporization chamber 10 through the connection line 22 to the growth chamber 12, and using the plasma generation device 14 to radicalize the chalcogen precursor gas supplied into the growth chamber 12. The chalcogen precursor 2 may be solid.

The first supply line 20 may be further provided with a first carrier gas. The first carrier gas may help supply the growth chamber 12 with the hydrogen gas and the chalcogen precursor gas. The first carrier gas may be, for example, argon.

Referring to FIGS. 1 and 2B, the growth chamber 12 may be provided with a radicalized transition metal precursor 106. The radicalized transition metal precursor 106 may include an unpaired electron and have relatively large reactivity. The supply of the radicalized transition metal precursor 106 into the growth chamber 12 may include allowing a transition metal precursor 3 to be vaporized to form a transition metal precursor gas, supplying the transition metal precursor gas through the second supply line 26 to the growth chamber 12, and using the plasma generation device 14 to radicalize the transition metal precursor gas supplied into the growth chamber 12.

The transition metal precursor 3 may be liquid or solid. The liquid or solid transition metal precursor 3 may be vaporized in the bubbler chamber 30, and a second carrier gas supplied through the third supply line 28 may be used to supply the transition metal precursor 3 through the second supply line 26. The second carrier gas may be, for example, argon.

The hydrogen radicals 103 may cause defects 107 to form on the first two-dimensional material layer 1. The hydrogen radical 103 may react with the first chalcogen atom 102 of the first two-dimensional material layer 1, and thus the first chalcogen atom 102 may be separated from the first transition metal atom 101. The defect 107 may be formed at a location from which the first chalcogen atom 102 is separated. The separated first chalcogen atom 102 and the hydrogen radical 103 may be combined to form a hydrogen chalcogenide 105. The hydrogen chalcogenide 105 may be, for example, H₂S, H₂Se, or H₂Te.

Referring to FIG. 2C, the radicalized transition metal precursor 106 may react with the first two-dimensional material layer 1. The radicalized transition metal precursor 106 and the first two-dimensional material layer 1 may react with each other at a position of the defect 107 of the first two-dimensional material layer 1. A second transition metal atom 108 combined with the first transition metal atom 101 may be formed by the reaction between the radicalized transition metal precursor 106 and the first two-dimensional material layer 1. The second transition metal atom 108 may be, for example, a molybdenum (Mo) atom or a tungsten (W) atom. When the second transition metal atom 108 is a molybdenum atom, the transition metal precursor 3 may be, for example, MoCl₅.

The second transition metal atom 108 may react with the radicalized chalcogen precursor 104. A second chalcogen atom 109 combined with the second transition metal atom 108 may be formed by the reaction between the radicalized chalcogen precursor 104 and the second transition metal atom 108. The second chalcogen atom 109 may include, for example, sulfur, selenium, or tellurium. When the second chalcogen atom 109 includes a selenium atom, for example, the chalcogen precursor 2 may be Se₈ and the radicalized chalcogen precursor 104 may be Se₆ or Se₇.

Referring to FIG. 2D, the combination of the second transition metal atom 108 and the second chalcogen atom 109 may be repeated due to the radicalized transition metal precursors 106 and the radicalized chalcogen precursors 104.

Referring to FIG. 2E, repetition of the combination of the second transition metal atom 108 and the second chalcogen atom 109 may induce an increase in size of a structure obtained by the combination of the second transition metal atoms 108 and the second chalcogen atoms 109. The structure, which is obtained by the combination of the second transition metal atoms 108 and the second chalcogen atoms 109, may grow along a plane defined by the first direction D1 and the second direction D2. An increase in size of the structure which is obtained by the combination of the second transition metal atoms 108 and the second chalcogen atoms 109, may cause a separation of the second transition metal atom 108 from the first transition metal atom 101 with which the second transition metal atom 108 is combined. The separation of the second transition metal atom 108 from the first transition metal atom 101 may form again the defect 107 on the first two-dimensional material layer 1.

Referring to FIG. 2F, the radicalized chalcogen precursor 104 may react with the first two-dimensional material layer 1 at the defect 107 of the first two-dimensional material layer 1. The second chalcogen atom 109 combined with the first transition metal atom 101 may be formed by the reaction between the radicalized chalcogen precursor 104 and the first two-dimensional material layer 1. The second chalcogen atom 109, which is combined with the first transition metal atom 101, may be disposed between the first transition metal atom 101 and the second transition metal atom 108.

The structures obtained by the combination of the second transition metal atoms 108 and the second chalcogen atoms 109 may be connected to each other, and a second two-dimensional material layer 4 may be formed which includes the second transition metal atoms 108 and the second chalcogen atoms 109. The formation of the second two-dimensional material layer 4 may form a stack structure including the second two-dimensional material layer 4 on the first two-dimensional material layer 1.

In a method of fabricating the stack structure according to some embodiments, as the plasma generation device 14 is used to form the second two-dimensional material layer 4 on the first two-dimensional material layer 1, the second two-dimensional material layer 4 may be formed to have the same crystal orientation as that of the first two-dimensional material layer 1.

In a method of fabricating the stack structure according to some embodiments, as the plasma generation device 14 is used to form the second two-dimensional material layer 4 on the first two-dimensional material layer 1, the second two-dimensional material layer 4 may be formed to have a large size on the first two-dimensional material layer 1.

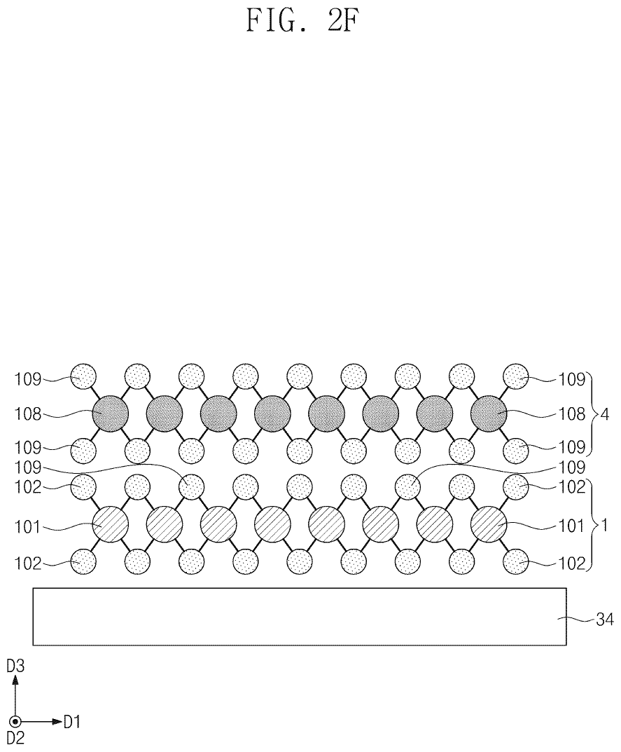

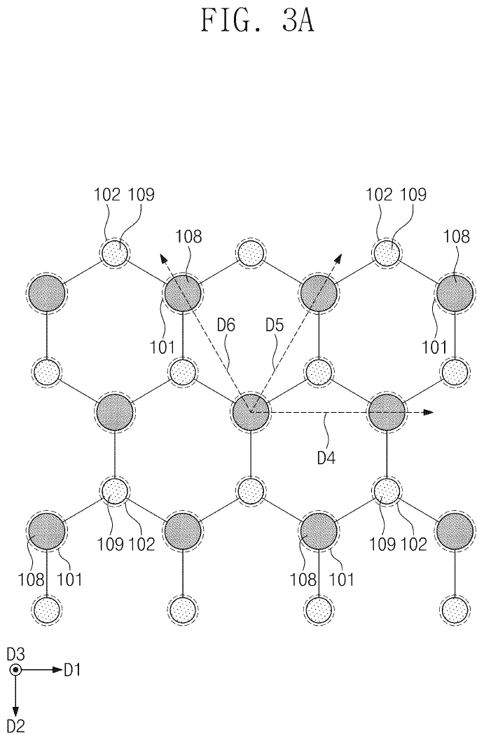

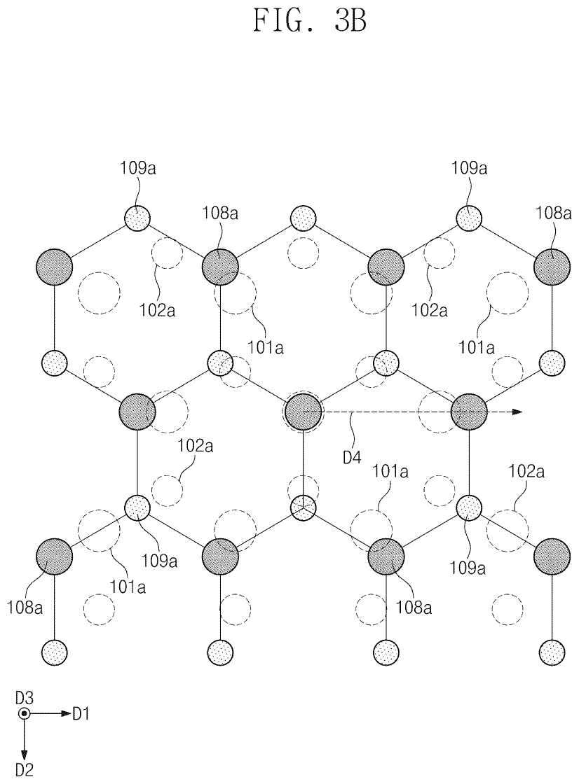

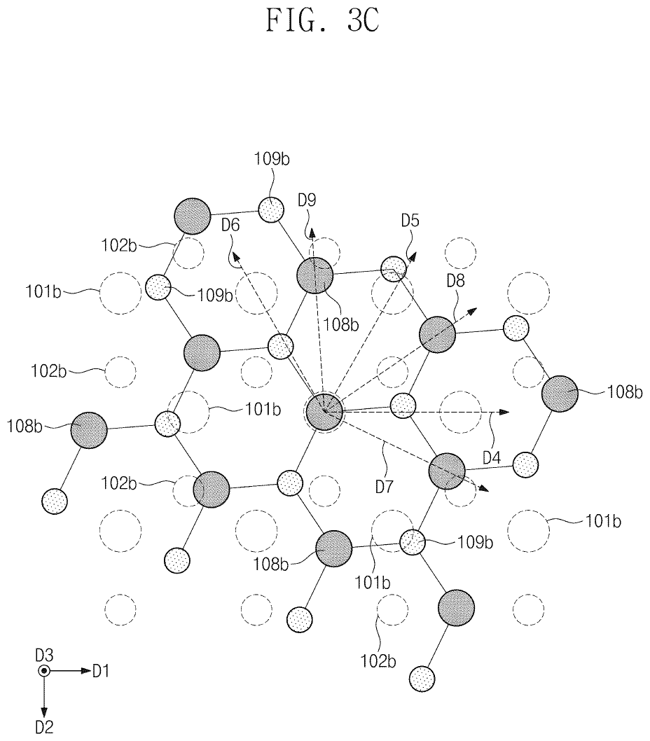

FIG. 3A illustrates the crystal orientation of a stack structure according to some embodiments.

Referring to FIG. 3A, a stack structure according to some embodiments may have a single-crystalline structure in which a first two-dimensional material layer and a second two-dimensional material layer have the same crystal orientation. The first transition metal atom 101 and the second transition metal atom 108 may be the same transition metal, and the first chalcogen atom 102 and the second chalcogen atom 109 may be the same chalcogen. Therefore, no lattice mismatch may occur between the first two-dimensional material layer and the second two-dimensional material layer.

The first transition metal atoms 101 may overlap in the third direction D3 with corresponding second transition metal atoms 108. The first chalcogen atoms 102 may overlap in the third direction D3 with corresponding second chalcogen atoms 109. An interatomic distance between the first transition metal atoms 101 and the first chalcogen atoms 102 of the first two-dimensional material layer may be the same as that between the second transition metal atoms 108 and the second chalcogen atoms 109 of the second two-dimensional material layer.

A single first transition metal atom 101 may be arranged in one of a fourth direction D4, a fifth direction D5, and a sixth direction D6 with respect to its adjacent first transition metal atom 101. A single second transition metal atom 108 may be arranged in one of the fourth direction D4, the fifth direction D5, and the sixth direction D6 with respect to its adjacent second transition metal atom 108. The fourth direction D4, the fifth direction D5, and the sixth direction D6 may be directions parallel to a plane defined by the first direction D1 and the second direction D2. The fourth direction D4, the fifth direction D5, and the sixth direction D6 may intersect each other. For example, the fourth direction D4, the fifth direction D5, and the sixth direction D6 may be horizontal directions that intersect each other.

As discussed above, the first transition metal atoms 101 and the second transition metal atoms 108 may be arranged in the same direction, and the first two-dimensional material layer and the second two-dimensional material layer may have the same crystal orientation.

FIG. 3B illustrates the crystal orientation of a stack structure according to some embodiments.

Referring to FIG. 3B, a stack structure according to some embodiments may have a single-crystalline structure in which a first two-dimensional material layer and a second two-dimensional material layer have the same crystal orientation. A first transition metal atom 101a and a second transition metal atom 108a may be different transition metals. Therefore, a lattice mismatch may occur between the first two-dimensional material layer and the second two-dimensional material layer.

One or more of the first transition metal atoms 101a may overlap in the third direction D3 with the second transition metal atoms 108a. One or more of first chalcogen atoms 102a may overlap in the third direction D3 with second chalcogen atoms 109a. A mismatch between the first two-dimensional material layer and the second two-dimensional material layer may cause the first transition metal atoms 101a to include a first transition metal atom 101a that does not overlap in the third direction D3 with the second transition metal atom 108a, and may cause the first chalcogen atoms 102a to include a first chalcogen atom 102a that does not overlap in the third direction D3 with the second chalcogen atom 109a.

An interatomic distance between the first transition metal atoms 101a and the first chalcogen atoms 102a of the first two-dimensional material layer may be different from that between the second transition metal atoms 108a and the second chalcogen atoms 109a of the second two-dimensional material layer. For example, the interatomic distance between the first transition metal atoms 101a and the first chalcogen atoms 102a may be less than that between the second transition metal atoms 108a and the second chalcogen atoms 109a.

A single first transition metal atom 101a may be arranged in the fourth direction D4 with respect to its adjacent first transition metal atom 101a. A single second transition metal atom 108a may be arranged in the fourth direction D4 with respect to its adjacent second transition metal atom 108a.

Even when the first transition metal atom 101a and the second transition metal atom 108a are different transition metals, the first transition metal atoms 101a and the second transition metal atoms 108a may be arranged in the same direction, and the first two-dimensional material layer and the second two-dimensional material layer may have the same crystal orientation.

FIG. 3C illustrates the crystal orientation of a stack structure according to a comparative example.

Referring to FIG. 3C, a stack structure according to a comparative example may be configured such that a first two-dimensional material layer and a second two-dimensional material layer have different crystal orientations.

A single first transition metal atom 101b may be arranged in one of the fourth direction D4, the fifth direction D5, and the sixth direction D6 with respect to its adjacent first transition metal atom 101b. A single second transition metal atom 108b may be arranged in one of a seventh direction D7, an eighth direction D8, and a ninth direction D9 with respect to its adjacent second transition metal atom 108b. The seventh direction D7, the eighth direction D8, and the ninth direction D9 may be parallel to a plane defined by the first direction D1 and the second direction D2. The fourth to ninth directions D4 to D9 may intersect each other. For example, the fourth to ninth directions D4 to D9 may be horizontal directions that intersect each other.

As discussed above, the first transition metal atoms 101b and the second transition metal atoms 108b may be arranged in different directions, and the first two-dimensional material layer and the second two-dimensional material layer may have different crystal orientations.

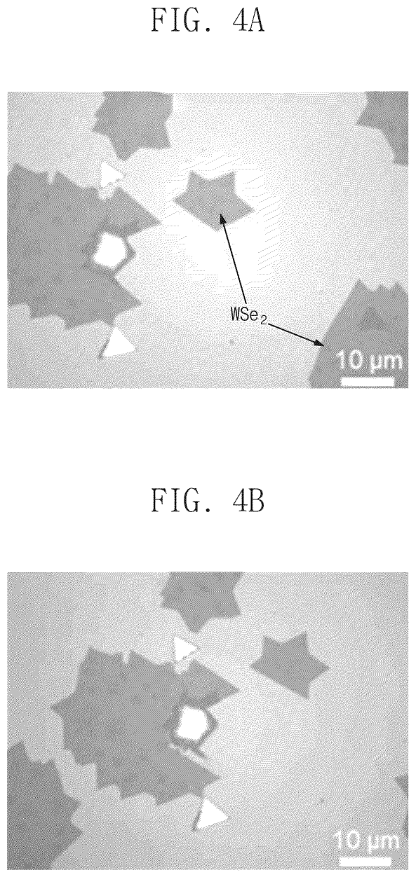

FIGS. 4A and 4B illustrate optical microscopic images showing results by a method of fabricating a stack structure according to a comparative example.

Referring to FIGS. 4A and 4B, a method without the plasma generation device 14 is performed to form MoSe₂ on WSe₂. Except the plasma generation device 14, the method is similar to that discussed in FIGS. 1 to 2F.

In FIG. 4A, it is ascertained that WSe₂ is present before MoSe₂ is formed. In FIG. 4B, even when performing a method of forming MoSe₂, it is ascertained that color and brightness of WSe₂ are not changed, and that MoSe₂ is not formed on WSe₂.

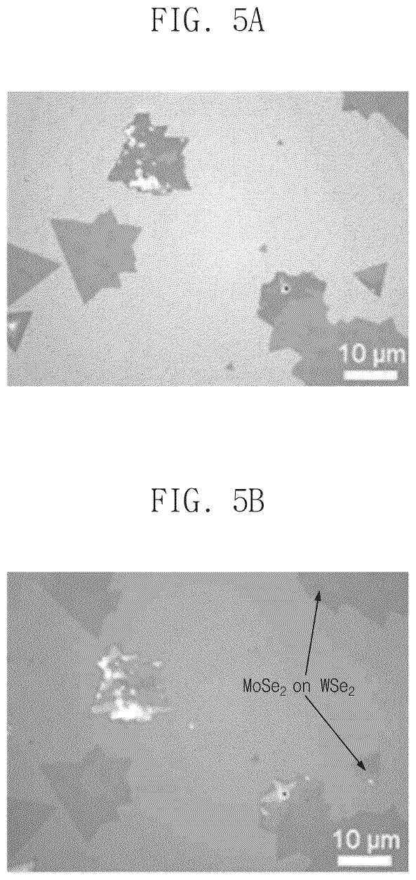

FIGS. 5A and 5B illustrate optical microscopic images showing results by a method of fabricating a stack structure according to some embodiments.

Referring to FIGS. 5A and 5B, a method is performed to form MoSe₂ on WSe₂ according to some embodiments. The fabrication method is similar to that discussed with reference to FIGS. 1 to 2F.

In FIG. 5A, it is ascertained that WSe₂ is present before MoSe₂ is formed. In FIG. 5B, a method of forming MoSe₂ is performed. It is ascertained that MoSe₂ has color and brightness different from those of WSe₂ depicted in FIG. 5A, and that MoSe₂ is formed on WSe₂.

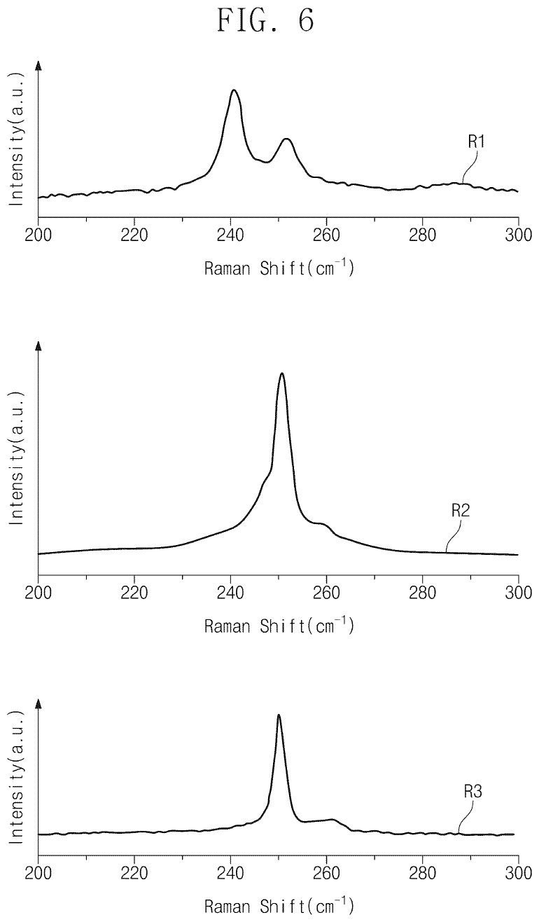

FIG. 6 illustrates a graph showing the Raman spectrum of a stack structure according to some embodiments.

Referring to FIG. 6, there are illustrated a Raman spectrum R1 of a stack structure in which MoSe₂ is formed on WSe₂ by a method of fabricating a stack structure according to some embodiments, a Raman spectrum R2 of a stack structure in which MoSe₂ is formed on WSe₂ by a method without the plasma generation device 14, and a Raman spectrum R3 of pristine WSe₂.

As shown in FIG. 6, Raman mode of MoSe₂ is observed in the Raman spectrum R1 of a stack structure formed by a method of fabricating a stack structure according to some embodiments.

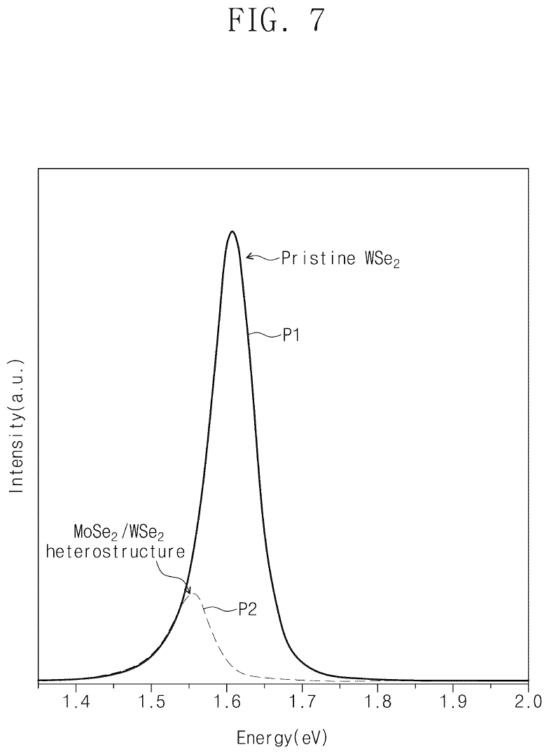

FIG. 7 illustrates the photoluminescence spectrum of a stack structure according to some embodiments.

Referring to FIG. 7, there are illustrated a photoluminescence spectrum P1 of pristine WSe₂ and a photoluminescence spectrum P2 of a stack structure in which MoSe₂ is formed on WSe₂ by a method of fabricating a stack structure according to some embodiments.

As shown in FIG. 7, there is ascertained a variation in peak position of the photoluminescence spectrum P2 of a stack structure in which MoSe₂ is formed on WSe₂ by a method of fabricating a stack structure according to some embodiments. Therefore, it is ascertained that the plasma generation device 14 forms a stack structure according to some embodiments.

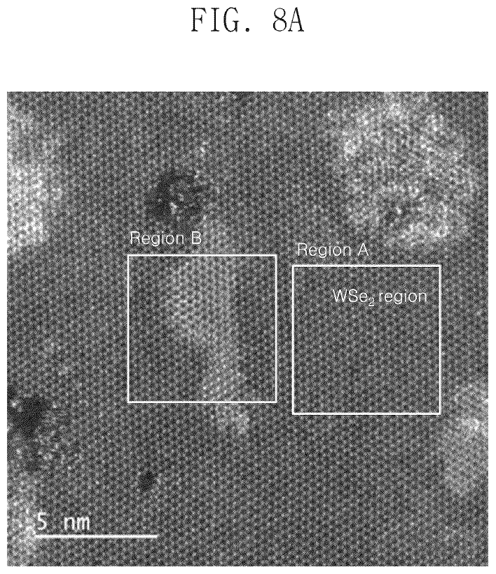

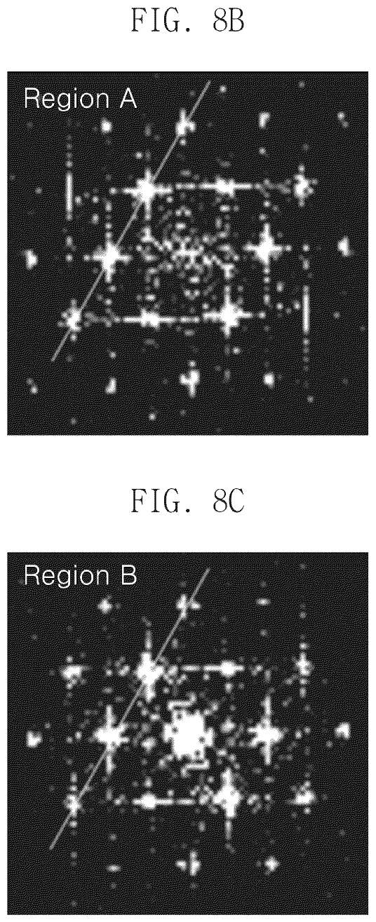

FIGS. 8A, 8B, and 8C illustrate images showing the crystal orientation of a stack structure according to some embodiments.

FIG. 8A is a transmission electron microscope (TEM) image of a stack structure in which MoSe₂ is formed on WSe₂ for 30 minutes according to some embodiments, FIG. 8B is an electron diffraction image showing Region A of in FIG. 8B, and FIG. 8C is an electron diffraction image showing Region B of FIG. 8A.

Referring to FIGS. 8A, 8B, and 8C, Region A is a WSe₂ area where MoSe₂ is not formed, and Region B is an area where MoSe₂ is formed on WSe₂. Referring to an electron diffraction image of Region A depicted in FIG. 8B and an electron diffraction image of Region B depicted in FIG. 8C, it is observed that MoSe₂ is formed on WSe₂ wherein the crystal orientation of MoSe₂ is the same as the crystal orientation of WSe₂.

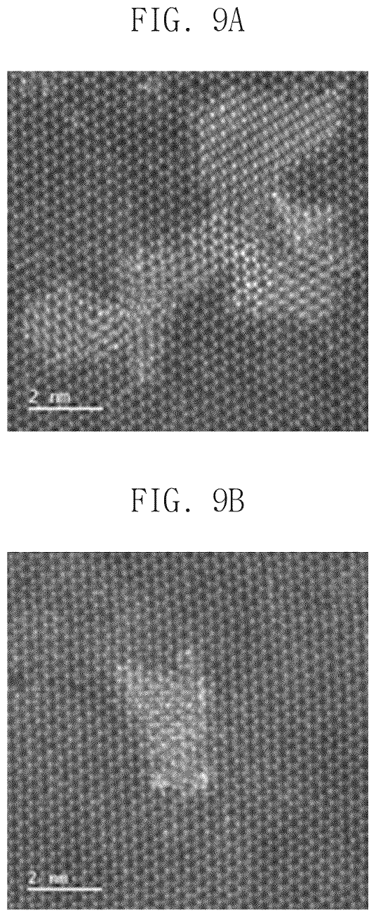

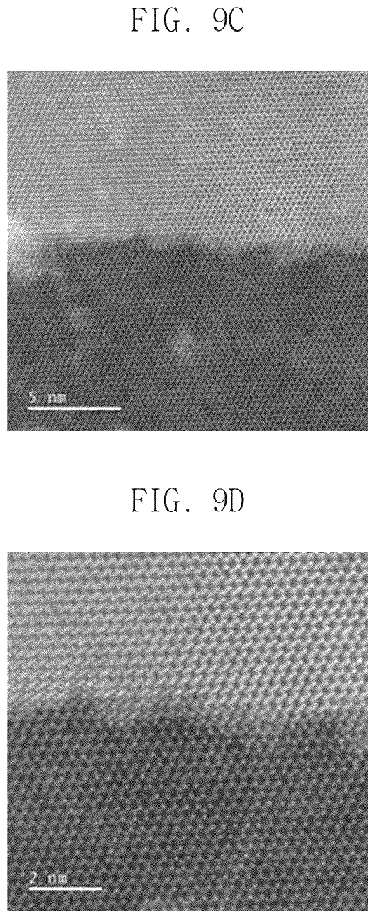

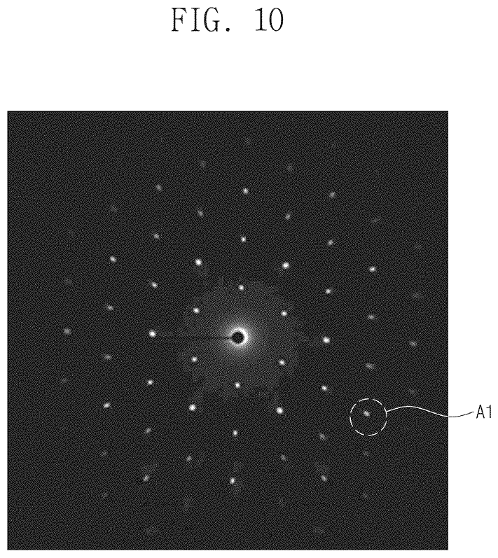

FIGS. 9A, 9B, 9C, and 9D illustrate transmission electron microscope (TEM) images showing a stack structure according to some embodiments.

FIGS. 9A and 9B are transmission electron microscope (TEM) images of a stack structure in which MoSe₂ is formed on WSe₂ for 30 minutes according to some embodiments, and FIGS. 9C and 9D are transmission electron microscope (TEM) images of a stack structure in which MoSe₂ is formed on WSe₂ for 90 minutes according to some embodiments.

Referring to FIGS. 9A, 9B, 9C, and 9D, it is ascertained that a moiré pattern is formed in accordance with MoSe₂ formed on WSe₂.

FIG. 10 illustrates an electron diffraction pattern showing a lattice mismatch of a stack structure according to some embodiments.

Referring to FIG. 10, MoSe₂ is formed on WSe₂ according to some embodiments, and then there is obtained an electron diffraction image of MoSe₂ and WSe₂. It is ascertained in the obtained electron diffraction image that WSe₂ and MoSe₂ have the same crystal orientation.

On an area A1, it is ascertained that two spots are observed due to a lattice mismatch between WSe₂ and MoSe₂ (e.g., a difference in interatomic distance between WSe₂ and MoSe₂).

According to a single-crystalline stack structure of two-dimensional transition metal chalcogenide and a method of fabricating the same in accordance with some embodiments of the present inventive concepts, there may be fabricated a thin layer including a large-sized stack structure that includes two-dimensional material layers having the same crystal orientation.

The aforementioned description provides some embodiments for explaining the present inventive concepts. Therefore, the present inventive concepts are not limited to the embodiments described above, and it will be understood by one of ordinary skill in the art that variations in form and detail may be made therein without departing from the spirit and essential features of the present inventive concepts.

What is claimed is:

1. A method of fabricating a stack structure, the method comprising:
providing a growth chamber with a first two-dimensional material layer;
forming a defect on the first two-dimensional material layer; and
forming a second two-dimensional material layer on the first two-dimensional material layer,
wherein forming the second two-dimensional material layer includes:
supplying the growth chamber with a transition metal precursor and a chalcogen precursor; and
reacting the first two-dimensional material layer and the transition metal precursor with each other.

2. The method of claim 1, wherein forming the second two-dimensional material layer further includes radicalize the transition metal precursor.

3. The method of claim 2, wherein reacting the first two-dimensional material layer and the transition metal precursor includes reacting the radicalized transition metal precursor with the first two-dimensional material layer.

4. The method of claim 1, wherein reacting the first two-dimensional material layer and the transition metal precursor includes allowing the transition metal precursor to react at a position of the defect of the first two-dimensional material layer.

5. The method of claim 1, wherein the first two-dimensional material layer includes a first transition metal atom and a first chalcogen atom,
wherein reacting the first two-dimensional material layer and the transition metal precursor includes allowing a second transition metal atom included in the transition metal precursor to combine with the first transition metal atom included in the first two-dimensional material layer.

6. The method of claim 5, wherein forming the second two-dimensional material layer includes allowing a second chalcogen atom included in the chalcogen precursor to combine with the second transition metal atom.

7. The method of claim 5, wherein forming the second two-dimensional material layer includes separating from each other the first transition metal atom and the second transition metal atom that are combined with each other.

8. The method of claim 7, further comprising reacting the first transition metal atom separated from the second transition metal atom and the chalcogen precursor with each other.

9. The method of claim 8, wherein reacting the first transition metal atom and the chalcogen precursor includes forming a second chalcogen atom that is combined with the first transition metal atom.

10. The method of claim 1, forming the defect on the first two-dimensional material layer includes allowing the first two-dimensional material layer and a hydrogen radical to react with each other to separate a first chalcogen atom included in the first two-dimensional material layer from the first two-dimensional material layer.

11. A method of fabricating a stack structure, the method comprising:
providing a growth chamber with a first two-dimensional material layer;
forming a defect on the first two-dimensional material layer; and
forming a second two-dimensional material layer on the first two-dimensional material layer,
wherein forming the second two-dimensional material layer includes:
supplying the growth chamber with a transition metal precursor and a chalcogen precursor; and
radicalizing the transition metal precursor and the chalcogen precursor.

12. The method of claim 11, wherein the first two-dimensional material layer and the second two-dimensional material layer have the same crystal orientation.

13. The method of claim 11, wherein
the first two-dimensional material layer includes first transition metal atoms,
the second two-dimensional material layer includes second transition metal atoms, and
an arrangement direction of the first transition metal atoms is the same as an arrangement direction of the second transition metal atoms.

14. The method of claim 13, wherein the first transition metal atoms and the second transition metal atoms are different transition metals.

15. The method of claim 13, wherein the first transition metal atoms and the second transition metal atoms are the same transition metal.

16. The method of claim 11, wherein forming the defect on the first two-dimensional material layer includes:
supplying the growth chamber with a hydrogen gas; and
radicalizing the hydrogen gas to form a hydrogen radical.

17. The method of claim 11, wherein an interatomic distance of the first two-dimensional material layer is different from an interatomic distance of the second two-dimensional material layer.

18. A stack structure, comprising:
a first two-dimensional material layer that includes first transition metal atoms and first chalcogen atoms; and
a second two-dimensional material layer on the first two-dimensional material layer, the second two-dimensional material layer including second transition metal atoms and second chalcogen atoms,
wherein the first two-dimensional material layer and the second two-dimensional material layer have the same crystal orientation.

19. The stack structure of claim 18, wherein an arrangement direction of the first transition metal atoms is the same as an arrangement direction of the second transition metal atoms.

20. The stack structure of claim 18, wherein the first two-dimensional material layer further includes a second chalcogen atom,
wherein the second chalcogen atom of the first two-dimensional material layer is between the first transition metal atom and the second transition metal atom.
